(19) United States
(12) Patent Application Publication
(10) Pub. No.: US 2015/0255644 A1
(43) Pub. Date: Sep. 10, 2015

(54) SOLAR CELL

(71) Applicant: Panasonic Intellectual Property Management Co., Ltd., Osaka (JP)

(72) Inventors: Yasuko HIRAYAMA, Osaka (JP); Kenta MATSUYAMA, Osaka (JP); Satoru SHIMADA, Osaka (JP)

(21) Appl. No.: 14/719,767

(22) Filed: May 22, 2015

Related U.S. Application Data
(63) Continuation of application No. PCT/JP2013/006795, filed on Nov. 19, 2013.

(30) Foreign Application Priority Data
Nov. 29, 2012 (JP) 2012-261673

(51) Int. Cl. H01L 31/0224; H01L 31/0236

(52) U.S. Cl. CPC H01L 31/022425; H01L 31/02366

(57) ABSTRACT

A solar cell has a texture and is equipped with an electrode formed on the texture and including flakes in addition to conductive particulates, wherein an average value of the longest axis diameters of the flakes is larger than an average value of the distances between the vertices of the texture.

### CROSS REFERENCE TO RELATED APPLICATIONS

This application is a continuation under 35 U.S.C. §120 of PCT/JP2013/006795, filed Nov. 19, 2013, which is incorporated herein reference and which claimed priority under 35 U.S.C. §119 to Japanese Application No. 2012-261673, filed Nov. 29, 2012, the entire content of which is also incorporated herein by reference.

### TECHNICAL FIELD

The present invention generally relates to a solar cell.

### BACKGROUND ART

There has been known a technology in which texture elements having unevenness from several μm to several tens of μm are provided on the light-receiving face of a solar cell for the purpose of enhancing power generation efficiency in the solar cell. By providing texture elements, the reflection of light incident on the light-receiving face from the outside can be reduced, and the effect of optical confinement to the inside of the solar cell can also be enhanced (see, PATENT DOCUMENTS 1 and 2).

### CITATION LIST

### Patent Literature

### PATENT DOCUMENT 1

Japanese Patent Laid-Open Publication No. 2010-93194

### PATENT DOCUMENT 2

Japanese Patent Laid-Open Publication No. 2011-515872

### SUMMARY OF INVENTION

### Technical Problem

When an electrode is formed on a substrate provided with a texture element or on a thin film formed on the substrate, the contact resistance between the substrate or the thin film formed on the substrate and the electrode, or the resistance of the electrode itself, is desirably reduced as much as possible.

### Solution to Problem

The present invention is a solar cell comprising: a photoelectric conversion section provided with a texture element; and an electrode formed on the photoelectric conversion section, the electrode comprising a flake in addition to a conductive particulate, wherein an average value of major axis diameters of the flakes is larger than an average value of distances between vertexes of the texture elements.

### Advantageous Effects of Invention

According to the solar cell of the present invention, the contact resistance between a power generation section and an electrode of solar cells may be reduced, and the power generation efficiency of solar cells may be enhanced.

### BRIEF DESCRIPTION OF DRAWINGS

FIG. 1 is a plain view illustrating a structure of a solar cell in an embodiment of the present invention.

FIG. 2 is a sectional view illustrating a structure of a solar cell in an embodiment of the present invention.

FIG. 3 is a view describing a relation between texture elements and flakes in an embodiment of the present invention.

FIG. 4 is a view describing a conventional relation between texture elements and flakes.

FIG. 5 is a scanning electron microscope observation view showing a structure of collector electrodes in an embodiment of the present invention.

FIG. 6 is a scanning electron microscope observation photograph showing a structure of texture elements in an embodiment of the present invention.

### DESCRIPTION OF EMBODIMENT

Hereinafter, an embodiment of the present invention will be described in detail; however, the present invention is not limited to the embodiment. Moreover, the drawings which are referred to in the embodiment are schematically drawn, and the dimension ratios of components or the like drawn in the drawings are sometimes different from those in actual articles. Specific dimension ratios or the like should be determined in consideration of the following description.

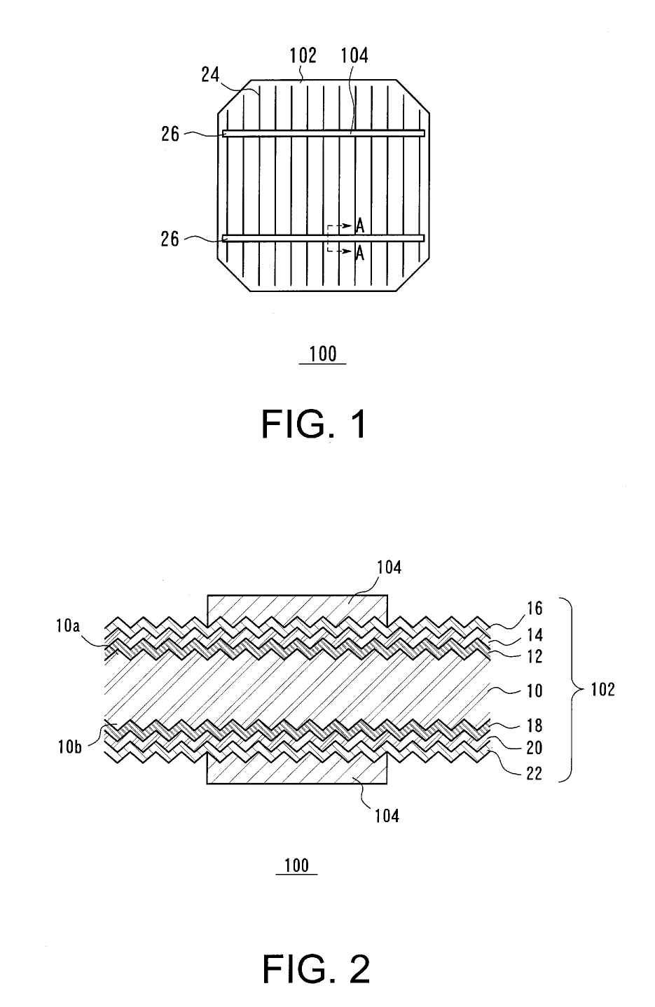

A solar cell in the present embodiment is constituted by including a photoelectric conversion section 102 and a collector electrode 104 as illustrated in FIG. 1 and FIG. 2. FIG. 2 is a sectional view along the line A-A in FIG. 1. A “light-receiving face” designates a principal face on which light is mainly incident from outside of the photoelectric conversion section 102, and a “reverse face” designates a principal face opposite the light-receiving face. For example, more than 50% to 100% of the sunlight incident on the photoelectric conversion section 102 is incident from the light-receiving face side.

The photoelectric conversion section 102 has a semiconductor junction such as a pn or pin junction or the like and is constituted of, for example, a crystalline semiconductor material such as monocrystalline silicon or polycrystalline silicon. The photoelectric conversion section 102 may be constituted by laminating an i-type amorphous silicon layer 12, a p-type amorphous silicon layer 14, and a transparent conductive layer 16 on the light-receiving face side of an n-type crystalline silicon substrate 10 and laminating an i-type amorphous silicon layer 18, an n-type amorphous silicon layer 20, and a conductive layer 22 on the reverse face side. The solar cell including such a constitution is called a heterojunction type solar cell and has a conversion efficiency that has been dramatically enhanced by interposing an intrinsic (i-type) amorphous silicon layer in the pn junction formed from the crystalline silicon and the p-type amorphous silicon layer. In addition, the conductive layer 22 on the reverse face side may be transparent or may not be transparent. Moreover, the photoelectric conversion section 102 is not limited to silicon and may be of any material so long as the material is a semiconductor material.

Texture elements 10a and 10b are preferably formed on both faces of the substrate 10 before laminating the respective layers. The texture elements 10a and 10b form uneven surface structures by which the surface reflection is suppressed to increase the amount of light absorption at the photoelectric conversion section 102.

For example, the texture elements 10a and 10b may be formed by conducting anisotropic etching of a (100) plane of the substrate 10 using an aqueous alkaline solution such as a sodium hydroxide (NaOH) aqueous solution, a potassium hydroxide (KOH) aqueous solution, or tetramethylammonium hydroxide (TMAH). The substrate 10 having the (100) plane is anisotropically etched along a (111) plane when immersed in the alkaline solution, and a large number of convex parts each having a substantially square pyramid shape are formed on the surface of the substrate 10. For example, the concentration of the aqueous alkaline solution contained in an etchant is favorably from 1.0 weight % to 7.5 weight %.

Moreover, a solution obtained by mixing an alcohol-based substance with the aqueous alkaline solution is also preferably used. Examples of the alcohol-based substance include isopropyl alcohol (IPA), cyclohexanediol, octanol, and so on. By using such a mixed solution, reattachment of a small piece or reaction product produced during anisotropic etching to the substrate 10 may be suppressed. The alcohol-based substance is favorably contained in an amount of about 1 weight % to about 10 weight %.

As another method for forming a texture element on the monocrystalline or polycrystalline substrate, metal particles such as silver particles are dispersed on the substrate 10, and then etching may be conducted with a mixed solution of hydrofluoric acid and hydrogen peroxide water.

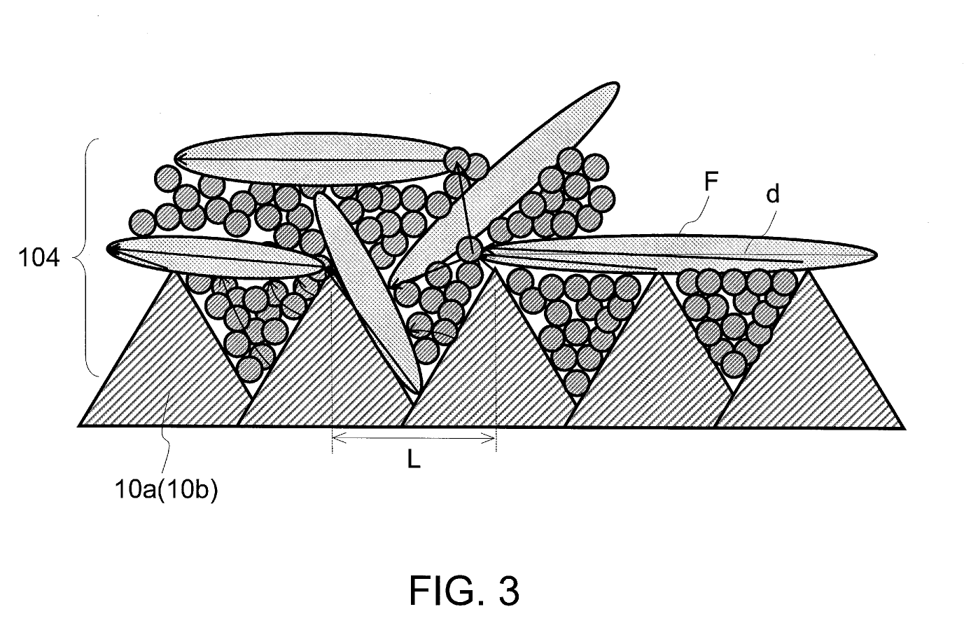

The size of the texture elements 10a and 10b may be adjusted by the composition ratio and concentration of a solution used for etching, the time for conducting etching, and the temperature condition at the time of etching. Here, the size of the texture elements 10a and 10b is represented, as illustrated in FIG. 3, by an interval L of vertexes adjacent to each other of the texture elements 10a and 10b. In a plane observation photograph of the surface of the substrate 10 with a scanning electron microscope (SEM), the area of each texture element approximated as a square is measured, and the square root of the average value of the areas for several hundred texture elements is determined as an average size of the texture elements 10a and 10b.

The i-type amorphous silicon layer 12, the p-type amorphous silicon layer 14, the i-type amorphous silicon layer 18, and the n-type amorphous silicon layer 20 may be formed by PECVD (Plasma Enhanced Chemical Vapor Deposition), Cat-CVD (Catalytic Chemical Vapor Deposition), a sputtering method, or the like. With respect to PECVD, any of an RF Plasma CVD method, a high frequency VHF Plasma CVD method, and a Micro Wave Plasma CVD method may be used.

For example, a raw material gas obtained by diluting silane (SiH₄) with hydrogen (H₂) is used for film-forming of the i-type amorphous silicon layers 12 and 18 by CVD. In the case of the p-type amorphous silicon layer 14, there may be used a raw material gas obtained by adding diborane (B₂H₆) to silane and diluting the resultant mixture with hydrogen (H₂). In the case of the n-type amorphous silicon layer 20, there may be used a raw material gas obtained by adding phosphine (PH₃) to silane and diluting the resultant mixture with hydrogen (H₂).

For example, the i-type amorphous silicon layer 12 having a thickness of about 5 nm is formed on the light-receiving face side of the substrate 10, and further the p-type amorphous silicon layer 14 having a thickness of about 5 nm is formed. Moreover, the i-type amorphous silicon layer 18 having a thickness of about 5 nm is formed on the reverse face side of the substrate 10, and further the n-type amorphous silicon layer 20 having a thickness of about 20 nm is formed. In addition, since the thickness of each layer is sufficiently thin, the shape of each layer reflects the shape of texture elements 10a and 10b of the substrate 10. Specifically, the i-type amorphous silicon layer 12 and the p-type amorphous silicon layer 14 reflect the shape of the texture elements 10a of the substrate 10. The i-type amorphous silicon layer 18 and the n-type amorphous silicon layer 20 reflect the shape of the texture elements 10b of the substrate 10. Hereinafter, the texture elements formed on the layer are also referred to as texture elements 10a or 10b.

The transparent conductive layer 16 is constituted by containing at least one metal oxide such as indium oxide, zinc oxide, tin oxide, or titanium oxide. The metal oxide may be doped with a dopant such as tin, zinc, tungsten, antimony, titanium, cerium, or gallium. The constitution of the conductive layer 22 may be the same as or different from that of the transparent conductive layer 16. A metal film constituted from a material having a high reflectance such as Ag, Cu, Al, Sn, or Ni or a metal film constituted from an alloy thereof may be used as the conductive layer 22. Moreover, the conductive layer 22 may have a laminated structure of a transparent conductive film and a metal film. Thereby, the light incident from the light-receiving face reflects at the metal film, thereby enhancing the power generation efficiency. The transparent conductive layer 16 and the conductive layer 22 may be formed by a film-forming method such as a vapor deposition method, a CVD method, or a sputtering method.

The collector electrode 104 for taking out the generated power to the outside is provided on the light-receiving face and the reverse face of the photoelectric conversion section 102. The collector electrode 104 includes a finger 24. The finger 24 is an electrode for collecting carriers produced in the photoelectric conversion section 102. The fingers 24 are formed, for example, in a wire shape having a width of about 100 μm and are positioned at intervals of 2 mm in order to collect the carriers from the photoelectric conversion section 102 as evenly as possible. The collector electrode 104 may further be provided with a bus bar 26 for connecting the fingers 24 thereto. The bus bar 26 is an electrode for collecting a current of carriers collected by a plurality of fingers 24. The bus bar 26 is formed, for example, in a wire shape having a width of 1 mm. The bus bar 26 is positioned so as to cross the fingers 24 along the direction in which a connection member for connecting solar cells 100 to form a solar cell module is positioned. The number and area of the fingers 24 and bus bars 26 are appropriately set in consideration of the area and resistance of the solar cell 100. In addition, the collector electrode 104 may have a constitution in which the bus bar 26 is not provided.

In addition, the installation area of the collector electrode 104 provided on the light-receiving face side of the solar cell 100 is favorably made smaller than the installation area of the collector electrode 104 provided on the reverse face side. That is to say, the loss caused by the light being blocked off may be reduced by making the area in which the incident light is blocked off as small as possible on the light-receiving face side of the solar cell 100. On the other hand, since it is not necessary to take the incident light into consideration on the reverse face side, a collector electrode in place of the finger 24 and the bus bar 26 may be provided so as to cover the whole reverse face of the solar cell 100.

The collector electrode 104 may be formed using a conductive paste. The conductive paste may be a conductive paste containing a conductive filler, a binder, and an additive such as a solvent.

The conductive filler is mixed into the collector electrode for the purpose of obtaining the electrical conductivity of the collector electrode. As the conductive filler, a metal particle such as, for example, silver (Ag), copper (Cu), or nickel (Ni); carbon; and a conductive particulate such as a mixture thereof are used. Among the conductive fillers, the silver particle is more preferably used. In the silver particle to serve as a filler, silver particles having different sizes may be mixed or a silver particle having an uneven shape provided on the surface thereof may be mixed.

Furthermore, in the present embodiment, a flake of a conductive particle is mixed in the conductive paste. The flake means a powder particle of a conductive material having a diameter of the longest axis (major axis diameter) of a particle of 2 μm or more. The flake may be obtained, for example, by processing a granular conductive particle by means of a pulverizer in which a ball is used as a pulverizing medium, such as a tumbling mill, a planetary ball mill, a tower mill, or a medium agitation mill. The flake may be, for example, a material containing silver.

The binder is mixed for adhesion as a main purpose. It is required that the binder be excellent in wet resistance and heat resistance in order to maintain reliability. As the binder, for example, there may be applied at least one member selected from the group consisting of epoxy resins, acrylic resins, polyimide resins, phenol resins, urethane resins, and silicone resins, or a mixture or copolymer thereof. The solvent may be butyl carbitol acetate (BCA), or the like. As the additive, a rheology-adjusting agent, a plasticizer, a dispersant, a defoaming agent, or the like may be contained in addition to the solvent.

The finger 24 and the bus bar 26 may be formed by applying such a conductive paste in a desired pattern on the transparent conductive layer 16 and the conductive layer 22 by a method such as screen printing or offset printing and curing the conductive paste by heating. At this time, a network structure in which a large number of conductive fillers and flakes are fused with each other may be included by adjusting the characteristics of the conductive filler and the flake or adjusting the heating temperature. When the conductive filler and the flake of the finger 24 and the bus bar 26 have a network structure, a structure in which half or more of the conductive fillers and the flakes of the finger 24 and the bus bar 26 are fused and bound with each other may be confirmed in an observation range of the microscope observation. When an amorphous semiconductor layer or layers are contained in the solar cell 100, there is favorably used a conductive paste that is cured in the temperature range (200° C. or less) where the heat damage to each amorphous semiconductor layer is small, or that forms a network structure.

In the present embodiment, the flake F contained in the collector electrode 104 is constituted, as illustrated in the schematic diagram of a cross section in FIG. 3, so that the average value of the longest axis diameters d is larger than the average value of the distances L between the vertexes of the texture elements 10a and 10b. Thereby, a large number of flakes F are positioned so as to lie across a plurality of adjacent vertexes of the texture elements 10a and 10b. At this time, the flake F makes contact with each vertex, across which the flake F lies, of the texture elements 10a and 10b. Moreover, a certain proportion of the flakes F positioned in an oblique direction between adjacent vertexes of the texture elements 10a and 10b are present. In addition, the flake F and the texture elements 10a or 10b do not necessarily make direct contact with each other, but may make contact with each other through the conductive filler.

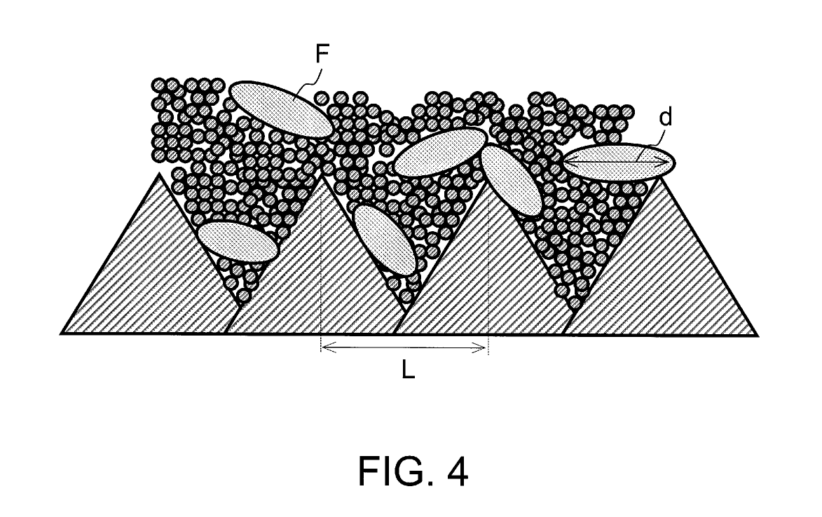

Here, the conventional structure is described with reference to FIG. 4. In addition, FIG. 4 is a view reduced in size so that the size of the texture elements 10a and 10b is the same as the size of the texture elements 10a and 10b in FIG. 3. In FIG. 3 and FIG. 4, the actual sizes of the flakes F and the actual sizes of the conductive fillers are the same. In the conventional structure, the average value of the longest axis diameters d of the flakes is smaller than the average value of the distances between vertexes of the texture elements. In this case, when a flake makes contact with a vertex of a texture element, the flake does not reach the vertex of the adjacent texture element. Accordingly, the flake only makes contact with the vertex of a texture element.

With the present embodiment, the contact resistance between the collector electrode 104 and the transparent conductive layer 16 and the contact resistance between the collector electrode 104 and the conductive layer 22 may be reduced by positioning the flake F so as to lie across a plurality of adjacent vertexes of the texture elements 10a and 10b. This is because the flake F does not have a grain boundary of a conductive material inside and therefore the resistance between the vertexes of the texture elements 10a and 10b connected by the flake F decreases.

Moreover, when the flake F is positioned in an oblique direction between the adjacent vertexes of the texture elements 10a and 10b, the contact portion of the flake F and the surface of the texture elements 10a and 10b increases and therefore a similar effect is exhibited.

Furthermore, the condition that the average area of the flakes F contained in the collector electrode 104 is larger than the average area of the rectangle formed by connecting the vertexes of the texture elements 10a and 10b is preferably satisfied. Thereby, the contact resistance between the collector electrode 104 and the transparent conductive layer 16 and the contact resistance between the collector electrode 104 and the conductive layer 22 may further be reduced.

Moreover, the flake F is favorably contained in the collector electrode 104 at about 25 weight % or more. Thereby, the possibility that the flake F makes contact with the texture elements 10a and 10b increases, and the possibility that the flakes F make contact with each other also increase. When the flakes F make contact with each other, there are formed flow channels through which carriers collected from the photoelectric conversion section 102 move as illustrated by arrows in FIG. 3. In addition, carriers may be collected from a large number of contact portions due to an increase in the number of contact portions between the flake F and the texture elements 10a or 10b. As mentioned above, since the flake F does not have a grain boundary of a conductive material inside, the carriers may move in the flake F at a lower resistance as compared with the case where the carriers move between conductive fillers. Accordingly, the resistance of the collector electrode 104 itself may be reduced. Moreover, the ratio of the conductive filler to the flake F in the collector electrode 104 favorably is higher in the region of the valley between vertexes than in the region above the vertexes of the texture elements. Thereby, the conductive fillers make contact with each other in the region of the valley between vertexes. As a result, flow channels through which carriers collected from the photoelectric conversion section 102 move are formed between adjacent texture elements and between the texture elements and the flake F. Thereby, the contact resistance between the collector electrode 104 and the transparent conductive layer 16 and the contact resistance between the collector electrode 104 and the conductive layer 22 may further be reduced.

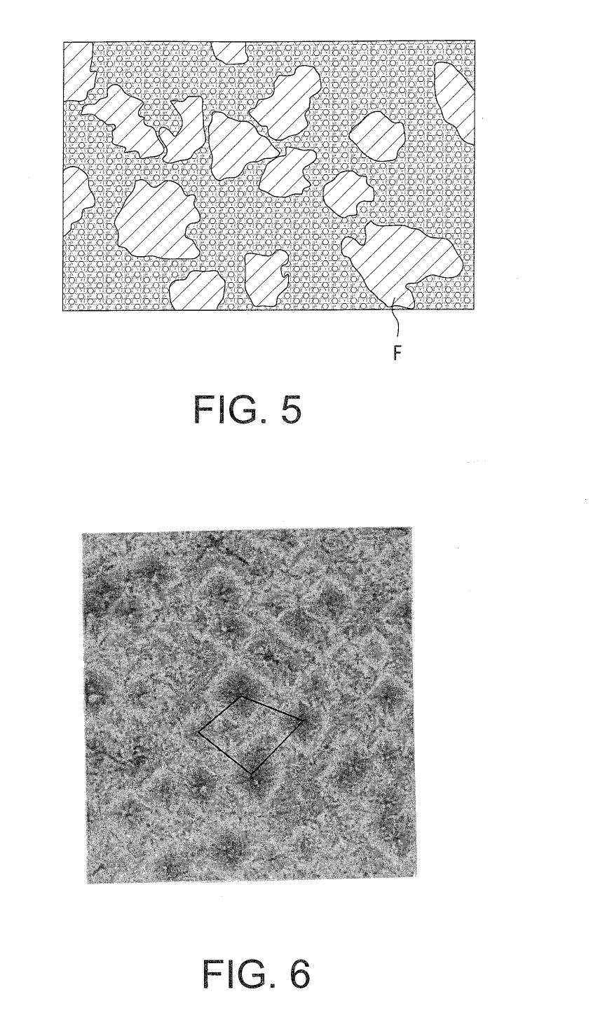

Hereinafter, the average value of the longest axis diameter d and the average area of the flakes F are described. In an SEM surface observation photograph of the collector electrode 104, the tabular flakes F are observed in the granular conductive filler as illustrated in FIG. 5. The average value of the longest axis diameters d of the flakes F may be calculated from the surface observation photograph of the collector electrode 104 with an SEM (Scanning Electron Microscope). For example, powder particles of the conductive material having a major axis diameter of the particle of 2 μm or more may be selected from the SEM surface observation photograph by an existing image processing technology, and the average value of the major axes (maximum diameters in the selected region) may be determined. Moreover, the average area of the flakes F contained in the collector electrode 104 may also be calculated from the surface observation photograph of the collector electrode 104 in the same manner with a scanning electron microscope (SEM). The average area of the flakes F that is a powder particle of the conductive material having a major axis of the particle of 2 μm or more may be determined from the SEM surface observation photograph by an existing image processing technology.

Hereinafter, the method for calculating the average area of the rectangles formed by connecting the vertexes of the texture elements 10a and 10b is described. In an SEM surface observation photograph of the light-receiving face or the reverse face of the substrate 10, the upper faces of the square pyramid texture elements 10a and 10b are observed as rectangles as illustrated in FIG. 6. The average area of the rectangles formed by connecting the vertexes of the texture elements 10a and 10b may also be calculated from the surface observation photograph of the light-receiving face or the reverse face of the substrate 10 with a scanning electron microscope (SEM). Thus, the average area of the rectangles formed by connecting the four adjacent vertexes of the texture elements 10a and 10b in the SEM surface observation photograph may be determined. In addition, the film thicknesses of the i-type amorphous silicon layer 12, the p-type amorphous silicon layer 14, the transparent conductive layer 16, and the i-type amorphous silicon layer 18, the n-type amorphous silicon layer 20, and the conductive layer 22 each formed on the substrate 10 are sufficiently thin, and therefore the average area of the rectangles formed by connecting the vertexes of the texture elements 10a and 10b may also be calculated in the same manner with the SEM surface observation photograph of the light-receiving face or the reverse face on which the layers are formed.

In addition, the scope of the application of the present invention is not limited to the solar cell in the present embodiment and may include a solar cell having a texture element on the light-receiving face or the reverse face. For example, the present invention may be applied to crystalline or thin film solar cells.

1. A solar cell comprising:
a photoelectric conversion section provided with a texture element; and
an electrode formed on the photoelectric conversion section, the electrode comprising a flake in addition to a conductive particle;
wherein an average value of major axis diameters of the flakes is larger than an average value of distances between vertexes of the texture elements.

2. The solar cell according to claim 1, wherein an average area of the flakes is larger than an average area of rectangles formed by connecting the vertexes of the texture elements.

3. The solar cell according to claim 1, wherein the flake is contained in the electrode at about 25 weight % or more.

4. The solar cell according to claim 1, wherein a ratio of the conductive particulate to the flake is higher in a region of a valley between the vertexes than in a region above the vertexes of the texture elements.

5. The solar cell according to claim 1, wherein the photoelectric conversion section comprises:
a crystalline semiconductor substrate provided with the texture element; and
an amorphous semiconductor layer formed on the crystalline semiconductor substrate.

6. The solar cell according to claim 5, wherein the photoelectric conversion section further comprises, on a light-receiving face side, a transparent conductive layer formed on the amorphous semiconductor layer.

7. The solar cell according to claim 5, wherein the photoelectric conversion section further comprises, on a reverse face side, a metal film layer formed on the amorphous semiconductor layer.
